(19) United States
(12) Patent Application Publication
(10) Pub. No.: US 2005/0219821 A1
(43) Pub. Date: Oct. 6, 2005

(54) Fan and heat sink arrangement

(75) Inventor: Chen Hui Lai, Taipei Hsien (TW)

Correspondence Address: BACON & THOMAS, PLLC, 625 SLATERS LANE, FOURTH FLOOR, ALEXANDRIA, VA, 22314, US

(73) Assignee: POWER COOLER ENTERPRISE CO., LTD., Taipei Hsien (TW)

(21) Appl. No.: 10/811,883

(22) Filed: Mar. 30, 2004

(51) Int. Cl. H05K 7/20

(52) U.S. Cl. 361/704

(57) ABSTRACT

A fan and heat sink arrangement includes a heat sink having a circular top center opening surrounded by radiation fins thereof, and a fan, which includes a main fan body suspended above the heat sink and an auxiliary fan body axially connected to the main fan body and received in the circular top center opening of the heat sink.

### BACKGROUND OF THE INVENTION

1. Field of the Invention

The present invention relates to a CPU cooler and more particularly, to a fan and heat sink arrangement, which greatly improves the heat dissipation efficiency of the fan.

2. Description of the Related Art

A conventional CPU cooler, as shown in FIG. 1, comprises a heat sink 11′ kept in close contact with the surface of a CPU 10′ at a circuit board 13′ and firmly secured to the circuit board 14′ by a bracket 13′, and a fan 12′ mounted on the top side of the heat sink 11′ adapted to induce currents of air toward the heat sink. This design of CPU cooler cannot dissipate heat from the CPU 10′ efficiently due to low capacity of the fan 12′ and high wind resistance in the narrow space around the bracket 13′ and the circuit board 14′.

### SUMMARY OF THE INVENTION

The present invention has been accomplished under the circumstances in view. It is the main object of the present invention to provide a fan and heat sink arrangement, which concentrates induced currents of air at the center area above the heat source to effectively dissipate heat from the heat source.

According to one aspect of the present invention, the fan and heat sink arrangement comprises fan and heat sink arrangement includes a heat sink having a circular top center opening surrounded by radiation fins thereof, and a fan, which comprises a main fan body suspended above the heat sink and an auxiliary fan body axially connected to the main fan body and received in the circular top center opening of the heat sink. According to another aspect of the present invention, the main fan body comprises an upper hub, a plurality of lower hubs connected in series to the upper hub, and a plurality of fan blades respectively fastened to and radially arranged around the upper hub and the lower hubs in a staggered manner

### BRIEF DESCRIPTION OF THE DRAWINGS

FIG. 1 a schematic drawing showing a fan and heat sink arrangement constructed according to the prior art.

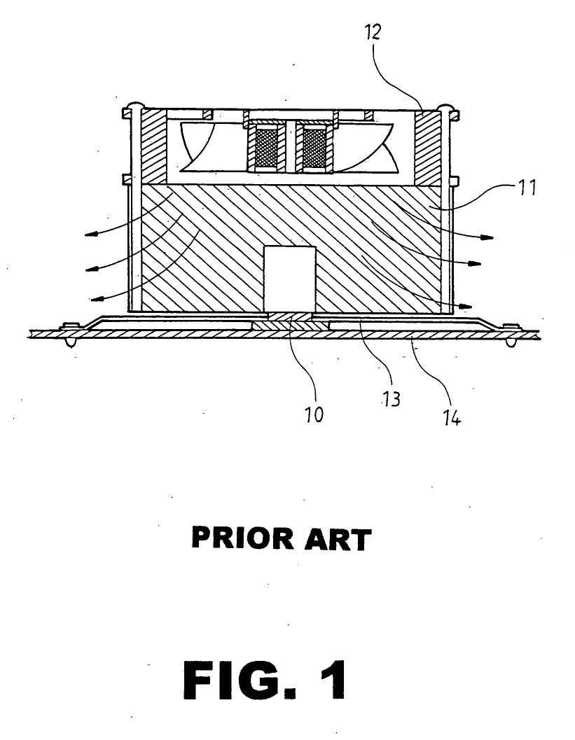

FIG. 2 is an exploded view of a fan and heat sink arrangement according to the present invention.

FIG. 3 is an exploded view of the main fan body for the fan and heat sink arrangement according to the present invention.

FIG. 4 is a schematic drawing showing the application of the present invention.

### DETAILED DESCRIPTION OF THE PREFERRED EMBODIMENT

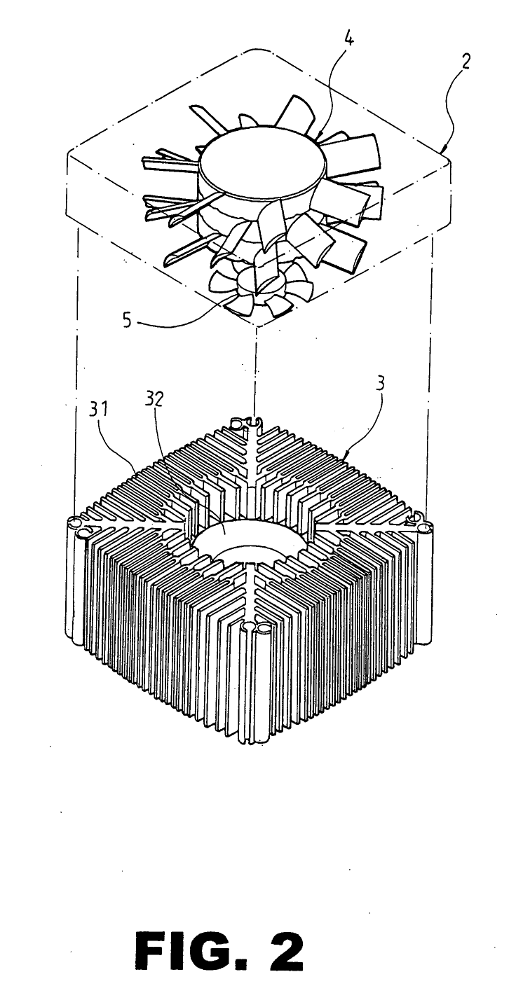

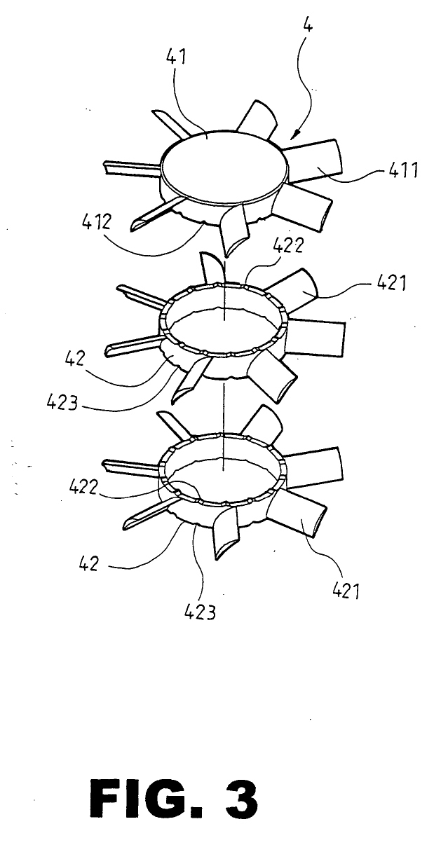

Referring to FIGS. 2 and 3, a fan and heat sink arrangement in accordance with the present invention is shown comprising a fan 2 and a heat sink 3. The fan 2 comprises a main fan body 4 and an auxiliary fan body 5 connected in series to the shaft of the main fan body 4.

The main fan body 4 comprises an upper hub 41 and a plurality of lower hubs 42 connected in series, and a plurality of fan blades 411 and 421 respectively radially arranged around the upper hub 41 and the lower hubs 42 in a staggered manner. The upper hub 41 has a plurality of equiangularly spaced bottom locating notches 412. The bottom locating notches 412 have a triangular cross section. The lower hubs 42 each have a plurality of equiangularly spaced top engagement ribs 422 and a plurality of equiangularly spaced bottom locating notches 423. By means of fitting the respective engagement ribs 422 into the respective bottom locating notches 421 and 423, the hubs 41 and 42 are connected in series.

The heat sink 3 comprises a plurality of radiation fins 32, and a circular center opening 32 surrounded by the radiation fins 32 and adapted to accommodate the auxiliary fan body 5.

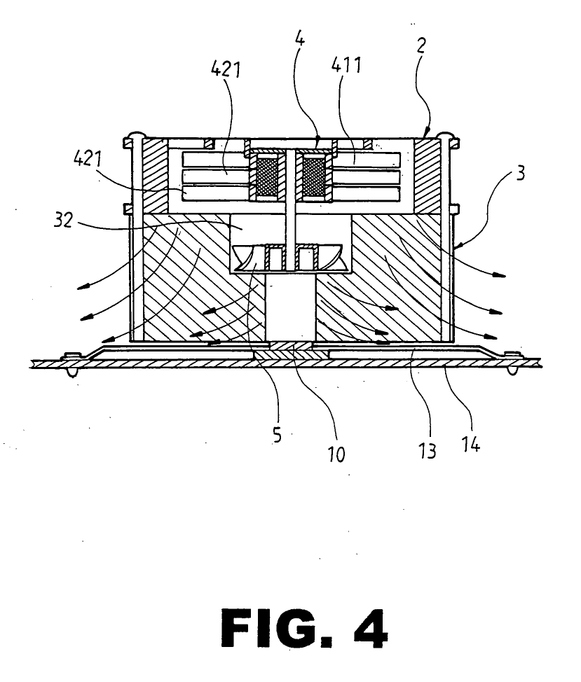

Referring to FIG. 4, the heat sink 3 is kept in close contact with the surface of a CPU 10 at a circuit board 14 and firmly secured to the circuit board 14 by a bracket 13. During operation of the fan 2, the fan blades 411 and 421 of the main fan body 4 are moved to induce strong currents of air, and the auxiliary fan body 5 is moved in the circular center opening 32 to concentrate induced currents of air at the center of the heat sink. Therefore, Jess wind resistance is produced in the space around the bracket 13 and the circuit board 14, and heat is quick carried away from the CPU 10 and the heat sink 3.

A prototype of fan and heat sink arrangement has been constructed with the features of FIGS. 2˜4. The fan and heat sink arrangement functions smoothly to provide all of the features discussed earlier.

Although a particular embodiment of the invention has been described in detail for purposes of illustration, various modifications and enhancements may be made without departing from the spirit and scope of the invention. Accordingly, the invention is not to be limited except as by the appended claims.

1. A fan and heat sink arrangement comprising a heat sink and a fan mounted on said heat sink, wherein said heat sink comprising a circular center opening disposed in a top side thereof and surrounded by radiation fins thereof; said fan comprises a main fan body suspended above said heat sink and an auxiliary fan body axially connected to said main fan body and received in the circular center opening of said heat sink, said main fan body comprising an upper hub, a plurality of lower hubs connected in series to said upper hub, and a plurality of fan blades respectively fastened to and radially arranged around said upper hub and said lower hubs in a staggered manner.

2. The fan and heat sink arrangement as claimed in claim 1, wherein said upper hub comprises a plurality of equiangularly spaced bottom locating notches; said lower hubs each comprise a plurality of equiangularly spaced top engagement ribs and a plurality of equiangularly spaced bottom locating notches; said upper hub and said lower hubs are connected in series by engaging the respective engagement ribs into the respective bottom locating notches.
